(19) United States
(12) Patent Application Publication
(10) Pub. No.: US 2024/0405056 A1
(43) Pub. Date: Dec. 5, 2024

(54) VERTICALLY-STACKED RGB MICRO-LIGHT-EMITTING DIODE HAVING CORNER MESA CONTACT STRUCTURES AND MANUFACTURING METHOD THEREOF

(71) Applicant: SUNDIODE KOREA, Seoul (KR)

(72) Inventors: James Chinmo KIM, Mountain View, CA (US); Sungsoo YI, Sunnyvale, CA (US)

(21) Appl. No.: 18/418,192

(22) Filed: Jan. 19, 2024

(30) Foreign Application Priority Data
Jun. 5, 2023 (KR) 10-2023-0072480

(51) Int. Cl. H01L 27/15

(52) U.S. Cl. CPC H01L 27/156

(57) ABSTRACT

The present inventive concept relates to a stacked-RGB micro-light-emitting diode having corner mesa contact structures and a manufacturing method thereof. The stacked-RGB micro-light-emitting diode having corner mesa contact structures includes a first light-emitting structure, a first tunnel junction layer, a first anode layer, a second anode layer, a second tunnel junction layer, a second light-emitting structure, and a third light-emitting structure, which are sequentially stacked on a substrate. According to the present inventive concept, it is possible to increase the lifespan of the micro-light-emitting diode by forming the corner mesa contact structure on each of the light-emitting structures by etching a vertically-stacked structure.

### CROSS-REFERENCE TO RELATED PATENT APPLICATION

This application claims the benefit of Korean Patent Application No. 10-2023-0072480, filed on Jun. 5, 2023, in the Korean Intellectual Property Office, the disclosure of which is incorporated herein in its entirety by reference.

### BACKGROUND OF THE INVENTIVE CONCEPT

### 1. Field of the Inventive Concept

The present inventive concept is related to an RGB micro-light-emitting diode consisting of three light sources of red (R), green (G), and blue (B), and more specifically, to a vertically-stacked-RGB micro light-emitting diode having corner mesa contact structures and a manufacturing method thereof.

### 2. Description of the Related Art

A light-emitting diode (LED) is a semiconductor device that emits light when a current flows in the forward direction, and it includes a PN junction where an n-type semiconductor and a p-type semiconductor are formed on active layers that generate light. A common method of manufacturing LEDs involves adding Mg to GaN to form a p-type semiconductor and adding Si to form an n-type semiconductor. LEDs are often used in displays such as TVs, billboards etc. signboards, and offer the advantages of low power consumption and long lifespan compared to traditional light sources.

However, traditional LEDs with a mesa structure fabricated by etching have issues with the active layers being exposed to the outside, in which the exposure leads to reduced internal quantum efficiency due to surface recombination at the exposed regions. The exposed regions are also susceptible to a leakage current due to surface damage and contamination caused by the plasma used during etching. Moreover, the surface recombination generates heat at the semiconductor surface, leading to structural defects such as dark line defects, which in turn reduce the lifespan of the LED.

Therefore, there is a need for the development of a light-emitting diode that can minimize the exposure of the active layers and enhance efficiency.

Furthermore, there is also a need for a method of electrically connecting each of the R, G and B sub-LEDs, when a micro-light-emitting diode with vertically-stacked R, G and B sub-LEDs forms a single pixel.

### SUMMARY OF THE INVENTIVE CONCEPT

The present inventive concept has been made in an effort to solve the above-described problems associated with prior art, and a first object of the present inventive concept is to provide a vertically-stacked-RGB micro-light-emitting diode having corner mesa contact structures.

A second object of the present inventive concept is to provide a method of manufacturing a vertically-stacked-RGB micro-light-emitting diode having corner mesa contact structures.

In order to achieve the above-mentioned first object, the present inventive concept provides a micro-light-emitting diode comprising: a substrate; a first light-emitting structure formed on the substrate; a first tunnel junction layer formed on the light-emitting structure; a first anode layer formed on the first tunnel junction layer; a second anode layer formed on the first anode layer; a second tunnel junction layer formed on the second anode layer; a second light-emitting structure formed on the second tunnel junction layer; and a third light-emitting structure formed on the second light-emitting structure, wherein the micro-light-emitting diode has first to third corner mesa contact structures formed by removing the higher layers relative to the first anode layer, the second anode, and a second n-type semiconductor layer in the second light-emitting structure to expose a portion of the upper surface of the first anode layer, the second anode layer, and the second n-type semiconductor layer, and wherein the first tunnel junction layer and the second tunnel junction layer comprise n⁺⁺-GaN layers and p⁺⁺-GaN layers, respectively, which are sequentially stacked in a symmetrical structure.

The micro-light-emitting diode may comprise a cathode connected to the first light-emitting structure and the third light-emitting structure and an anode deposited on the surfaces of the third light-emitting structure, the first corner mesa contact structure, and the second corner mesa contact structure.

The first anode layer and the second anode layer may consist of an n-type semiconductor layer, respectively, the first anode layer may be connected in a reverse bias to the current direction of the first light-emitting structure, and the second anode layer may be connected in a reverse bias to the current direction of the second light-emitting structure.

The micro-light-emitting diode may further comprise a current blocking layer formed between the first anode layer and the second anode layer, and the current blocking layer may consist of a p-type semiconductor or an insulating material.

The first light-emitting structure may generate light of a first wavelength, the second light-emitting structure may generate light of a second wavelength, and the third light-emitting structure may generate light of a third wavelength.

The light of the first wavelength may be blue (B), the light of the second wavelength may be green (G), and the light of the third wavelength may be red (R).

In order to achieve the above-mentioned second object, the present inventive concept provides a method of manufacturing a micro-light-emitting diode having corner mesa contact structures.

The micro-light-emitting diode may be manufactured by forming first to third contact holes on a vertically-stacked structure, forming a pixel mesa structure including the first to third contact holes as first to third corner mesa contact structures, respectively, and depositing a protective layer and a metal contact thereon.

The micro-light-emitting diode may be manufactured by forming a pixel mesa structure by etching the vertically-stacked structure, depositing and planarizing a protective film, forming first to third contact holes, removing the remaining protective film to form first to third corner mesa contact structures, and depositing a protective layer and a metal contact thereon.

The first corner mesa contact structure may be formed by removing the higher layers relative to the first anode layer to expose a portion of the upper surface of the first anode layer, the second corner mesa contact structure may be formed by removing the higher layers relative to the second anode layer to expose a portion of the upper surface of the second anode layer, and the third corner mesa contact structure may be formed by removing the higher layers relative to the second n-type semiconductor layer to expose a portion of the upper surface of the second n-type semiconductor layer.

According to the present inventive concept as described above, the micro-light-emitting diode has a mesa structure that is approximately perpendicular at the corners, which minimizes the exposure of the active layers to the external environment, thereby reducing the occurrence of surface recombination, which is a primary cause of leakage current. As a result, it is possible to increase the lifespan of the micro-light-emitting diode. Moreover, due to the vertical etching direction, the manufacturing process is easier, and the unit area of the micro-light-emitting diode can be reduced due to a stacked structure. Furthermore, the common electrode and other individual electrodes are formed on the same upper surface, which facilitates connection to external terminals in subsequent wiring processes, etc. and leads to a reduction in manufacturing costs. Particularly, forming electrical-contact with external terminals can be performed very simply and effectively.

### BRIEF DESCRIPTION OF THE DRAWINGS

The above and other features and advantages of the present inventive concept will become more apparent by describing in detail exemplary embodiments thereof with reference to the attached drawings in which:

FIG. 1 shows cross-sectional views and a perspective view of a micro-light-emitting diode according to an embodiment of the present inventive concept;

FIGS. 2 to 9 show perspective views illustrating the process of manufacturing a micro-light-emitting diode according to a first embodiment of the present inventive concept;

FIG. 10 show cross-sectional views and a perspective view of a micro-light-emitting diode according to an embodiment of the present inventive concept; and

FIGS. 11 to 21 show perspective views illustrating the process of manufacturing a micro-light-emitting diode according to a second embodiment of the present inventive concept.

### DETAILED DESCRIPTION OF THE INVENTIVE CONCEPT

As the present inventive concept allows for various changes and numerous embodiments, particular embodiments will be illustrated in the drawings and described in detail in the written description. However, this is not intended to limit the present inventive concept to particular modes of practice, and it is to be appreciated that all changes, equivalents, and substitutes that do not depart from the spirit and technical scope of the present inventive concept are encompassed in the present inventive concept. In the drawings, like reference numerals have been used throughout to designate like elements.

Unless defined otherwise, all terms used herein including technical or scientific terms have the same meaning as those generally understood by those skilled in the art to which the present inventive concept pertains. It will be further understood that terms defined in dictionaries that are commonly used should be interpreted as having meanings that are consistent with their meanings in the context of the relevant art and should not be interpreted as having ideal or excessively formal meanings unless clearly defined in the present application.

In this specification, “LED” and “light-emitting diode” have the same meaning and thus may be used interchangeably throughout the specification.

In this specification, the contact holes described later are formed independently of the order and are not interpreted as being limited to the order of the manufacturing method of the embodiment.

Hereinafter, various embodiments of the present inventive concept will be described in more detail with reference to the accompanying drawings.

### First Embodiment

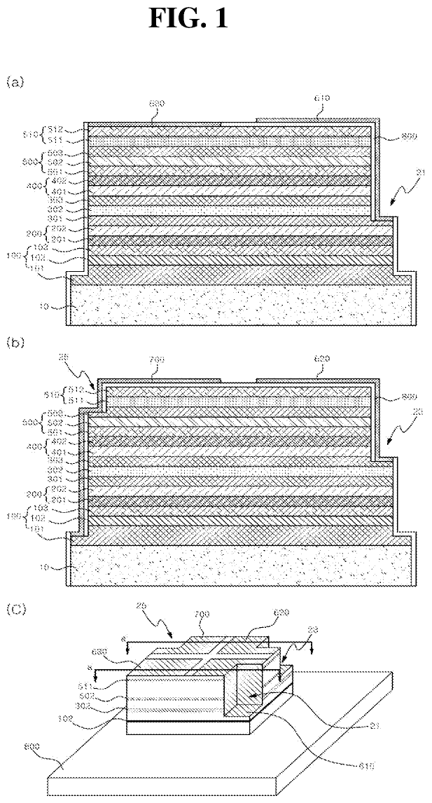

FIG. 1 shows cross-sectional views and a perspective view of a micro-light-emitting diode according to an embodiment of the present inventive concept. In FIG. 1, (a) and (b) represent cross-sectional views obtained by cutting the perspective view of (c) in the directions of a and a′, respectively. Here, (a) is a cross-sectional view obtained by cutting the perspective view of (c) in the direction of a, and (b) is a cross-sectional view obtained by cutting the perspective view of (c) in the direction of a′. In FIG. 1, (a) and (b) may have omitted the passivation layer for convenience of understanding, and the perspective view of (c) provides a more accurate structure.

Referring to FIG. 1, a substrate 10, a first light-emitting structure 100, a first tunnel junction layer 200, a first anode layer 301, a second anode layer 303, a second tunnel junction layer 400, a second light-emitting structure 500, and a third light-emitting structure 510 are sequentially stacked.

The substrate 10 may comprise at least one selected from the group consisting of Al₂O₃, SiC, GaN, GaP, GaAs, InP, and ZnO but is not limited thereto.

The first anode layer 301 and the second anode layer 303 may consist of an n-type semiconductor layer, respectively.

A current blocking layer 302 may be interposed between the first anode layer 301 and the second anode layer 303 to allow the current from the first anode layer 301 to flow towards the first light-emitting structure 100 and the current from the second anode layer 303 to flow towards the second light-emitting structure 500.

The current blocking layer 302 may consist of a p-type semiconductor or an insulating material.

The first tunnel junction layer 200 and the second tunnel junction layer 400 may comprise n⁺⁺-GaN layers 202 and 401 and p⁺⁺-GaN layers 201 and 402, respectively, which are sequentially stacked in a symmetrical structure with respect to the first anode layer 301 and the second anode layer 303. Due to the first tunnel junction layer 200 being connected to the bottom of the first anode layer 301, the first anode layer 301 may be connected in a reverse bias to the first light-emitting structure 100, and due to the second tunnel junction layer 400 being connected to the top of the second anode layer 303, the second anode layer 303 may be connected in a reverse bias to the second light-emitting structure 500.

The first light-emitting structure 100 may comprise a first n-type semiconductor layer 101, a first active layer 102, and a first p-type semiconductor layer 103, which are sequentially stacked. The second light-emitting structure 500 may comprise a second p-type semiconductor layer 501, a second active layer 502, and a second n-type semiconductor layer 503, which are sequentially stacked. The third light-emitting structure 510 may share the second n-type semiconductor layer 503 with the second light-emitting structure 500 and may comprise a third active layer 511 and a third p-type semiconductor layer 512, which are sequentially stacked on the second n-type semiconductor layer 503.

The first to third active layers may have a multi-quantum well structure.

The micro-light-emitting diode manufactured in an embodiment of the present inventive concept has a substantially rectangular planar shape when viewed from the top. Moreover, the rectangular planar shape is defined as having four corners. Furthermore, the micro-light-emitting diode illustrated in FIG. 1 has a vertically-stacked structure of R, G, and B components, forming a single pixel.

A first corner mesa contact structure 21 is formed at a first corner. The first corner mesa contact structure 21 is formed on the first anode layer 301, and the first anode layer 301 consists of an n-type semiconductor layer. The first tunnel junction layer 200 in a reverse bias state is formed at the bottom of the n-type semiconductor layer, and the first p-type semiconductor layer 103 is formed at the bottom of the first tunnel junction layer 200. Even though the first anode layer 301 has an n-type conductivity, current is supplied to the first active layer 102 through the first anode layer 301, the first tunnel junction layer 200, and the first p-type semiconductor layer 103.

To supply current to the first anode layer 301, a first anode 610 is formed on a portion of the exposed surface of the first anode layer 301, and the first anode 610 is connected to an upper part of the corner mesa contact structure.

A second corner mesa contact structure 23 is formed at a second corner opposite the first corner. The second corner is any of the corners other than the first corner of the substantially rectangular upper surface. The second corner mesa contact structure 23 is formed on the second anode layer 303 to expose a portion of the upper surface of the second anode layer 303. The second anode layer 303 consists of an n-type semiconductor layer, the second tunnel junction layer 400 in a reverse bias state is formed on the n-type semiconductor layer, and the second p-type semiconductor layer 501 is formed on the second tunnel junction layer 400. Even though the second anode layer 303 has an n-type conductivity, current is supplied to the second active layer 502 through the second anode layer 303, the second tunnel junction layer 400, and the second p-type semiconductor layer 501. To supply current to the second anode layer 303, a second anode 620 is formed on a portion of the exposed surface of the second anode layer 303, and the second anode 620 is connected to an upper part of the corner mesa contact structure.

A third corner mesa contact structure 25 is formed at a corner other than where the first corner and the second corner are formed. The third corner mesa contact structure 25 is formed on the second n-type semiconductor layer 503 to expose a portion of the upper surface of the second n-type semiconductor layer 503. A common cathode 700, which is connected to a portion of the exposed surface of the first n-type semiconductor layer 101, is formed on a portion of the exposed surface of the second n-type semiconductor layer 503, thus electrically connecting the first n-type semiconductor layer 101 and the second n-type semiconductor layer 503. The common cathode 700 is connected to an upper part of the corner mesa contact structure.

In addition, a third anode 630 is formed on a portion of the exposed surface of the third p-type semiconductor layer 512, which is the upper part of the third light-emitting structure 510, and the third anode 630 is connected to an upper part of the corner mesa contact structure. Current is supplied to the third active layer 511 through the third anode 630 and the third p-type semiconductor layer 512.

A passivation layer 800 is formed on the upper and side parts of the corner mesa contact structure, to which the first anode 610, the second anode 620, the third anode 630, and the common cathode 700 are connected, to act as an insulating layer.

Due to the above-described three corner mesa contact structures, three of the four corners are used to form the corner mesa contact structures, and as a result, the area occupied by the mesa structure can be minimized. Moreover, by forming the corner mesa contact structures by etching at the corners of the mesa structure, the side surface exposed by etching is reduced to less than half compared to the conventional approaches that form etched structures inside the mesa structure away from the corners, which minimizes the exposure of the active layers, thereby maximizing the efficiency of the micro-light-emitting diode.

Furthermore, within the rectangular plane at the top of the pixel mesa structure of the micro-light-emitting diode, the center has the highest light emission intensity, while the corner portions have relatively lower light emission intensity. This means that by utilizing the corner portions with lower light emission intensity as contact structures, the light emission efficiency of the micro-light-emitting diode can be improved.

To manufacture a micro-light-emitting diode having corner mesa contact structures using the vertically-stacked structure formed in the above order, the following process is performed.

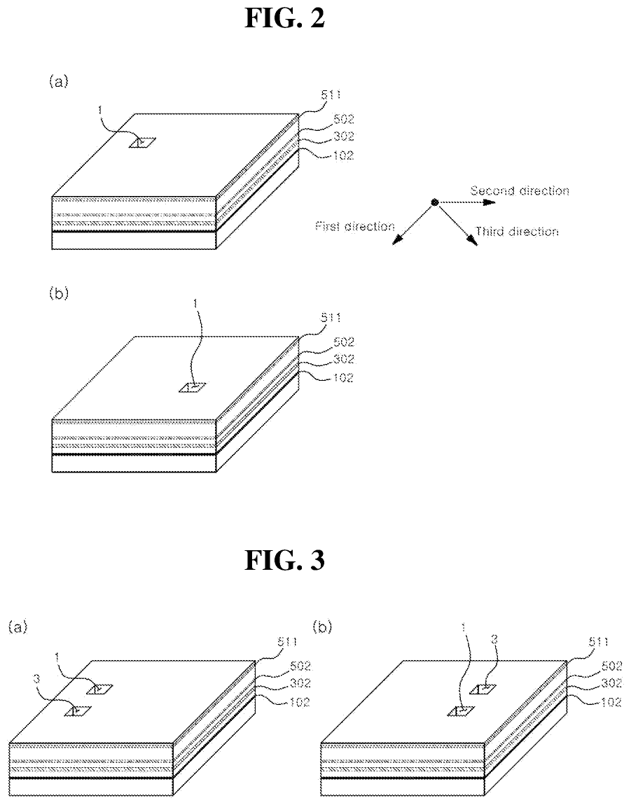

FIGS. 2 to 9 show perspective views illustrating the process of manufacturing a micro-light-emitting diode according to a first embodiment of the present inventive concept. The structure obtained by rotating (a) in FIGS. 2 to 9 by 180° is shown in (b), respectively.

Referring to FIGS. 2 to 9, the micro-light-emitting diode may be manufactured by a process including: a first step of forming a first contact hole at a first corner to form a first corner mesa contact structure on a vertically-stacked structure; a second step of forming a second contact hole to form a second corner mesa contact structure in a first direction with respect to the first contact hole; a third step of forming a third contact hole to form a third corner mesa contact structure in a second direction with respect to the second contact hole; a fourth step of forming a vertically-stacked structure having corner mesa contact structures on a first n-type semiconductor layer by etching the vertically-stacked structure including the first to third contact holes at the corners into a rectangular pixel mesa structure; a fifth step of forming a passivation layer on the vertically-stacked structure having corner mesa contact structures formed in the fourth step; a sixth step of etching the passivation layer for electrode connection of the vertically-stacked structure; a seventh step of forming a metal contact to connect to the top of the etched vertically-stacked structure; and an eighth step of dividing the metal contact formed in the seventh step into four parts by etching the metal contacts located on the top of the pixel mesa structure to be individually connected.

Referring to FIG. 2, the vertically-stacked structure illustrated in FIG. 1 is formed on a substrate. The vertically-stacked structure refers to the structure formed up to the third p-type semiconductor layer 512 through the MOCVD process.

First, in the first step, a first contact hole 1 is formed at a first corner using a conventional lithography process. One of the first anode layer 301, the second anode layer 303, and the second n-type semiconductor layer 503 is exposed through the first contact hole 1. The first contact hole 1 may be formed by removing the higher layers relative to the first anode layer 301 to expose a portion of the upper surface of the first anode layer 301.

In this embodiment, it is described that a portion of the upper surface of the first anode layer 301 is exposed through the first contact hole 1, but the layers exposed through the contact holes can be easily changed. That is, in the present inventive concept, the three contact holes expose the first anode layer 301, the second anode layer 303, and the second n-type semiconductor layer 503, respectively, but two or more contact holes do not share the exposed layers.

Referring to FIG. 3, in the second step, a second contact hole 3 is formed to form a second corner mesa contact structure in a first direction, which, in the perspective view of the figure, is vertical to the first contact hole 1, on the vertically-stacked structure. One of the first anode layer 301, the second anode layer 303, and the second n-type semiconductor layer 503 is exposed through the second contact hole 3. The second contact hole 3 may be formed by removing the higher layers relative to the second anode layer 303 to expose a portion of the upper surface of the second anode layer 303.

In this embodiment, it is described that a portion of the upper surface of the second anode layer 303 is exposed through the second contact hole 3, but the layers exposed through the contact holes can be easily changed.

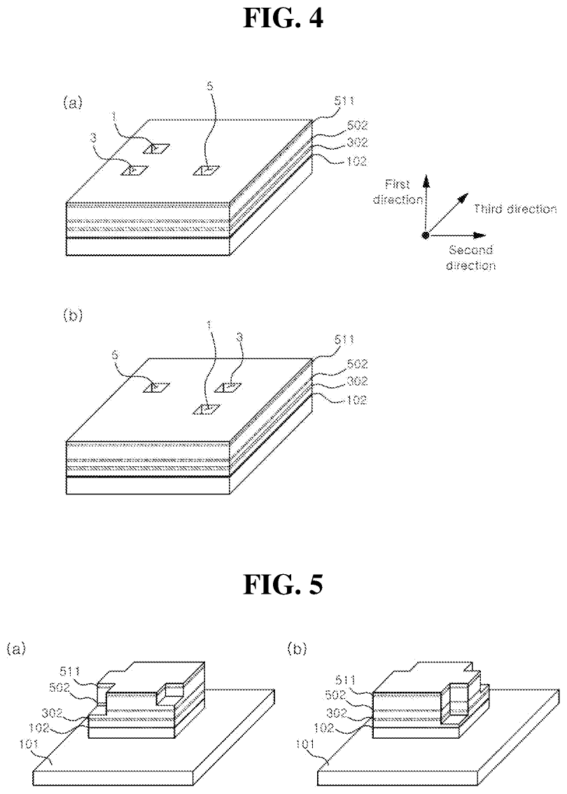

Referring to FIG. 4, in the third step, a third contact hole 5 is formed to form a third corner mesa contact structure in a second direction, which, in the perspective view of the figure, is transverse to the second contact hole 3, on the vertically-stacked structure. One of the first anode layer 301, the second anode layer 303, and the second n-type semiconductor layer 503 is exposed through the third contact hole 5. The third contact hole 5 may be formed by removing the higher layers relative to the second n-type semiconductor layer 503 to expose a portion of the upper surface of the second n-type semiconductor layer 503.

In this embodiment, it is described that a portion of the upper surface of the second n-type semiconductor layer 503 is exposed through the third contact hole 5, but the layers exposed through the contact holes can be easily changed.

Referring to FIG. 5, in the fourth step, a vertically-stacked structure having corner mesa contact structures is formed by etching the vertically-stacked structure, which includes the first contact hole 1 at the first corner, the second contact hole 3 at the second corner, the third contact hole 5 at the third corner, and no contact hole at the fourth corner, into a rectangular pixel mesa structure, down to the surface of the first n-type semiconductor layer 101.

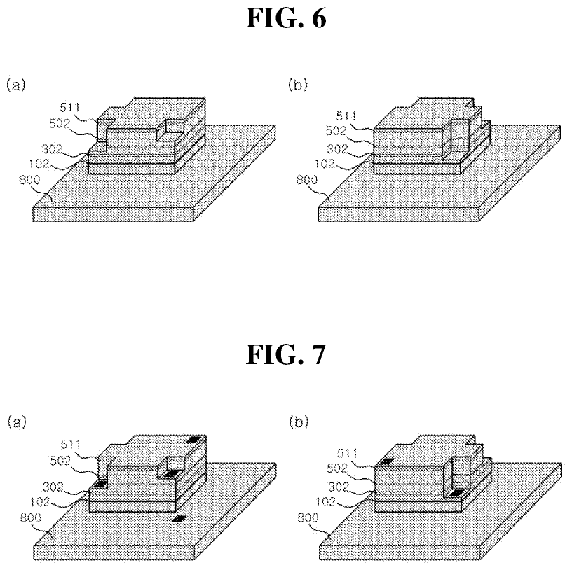

Referring to FIG. 6, in the fifth step, a passivation layer 800 is deposited on the vertically-stacked structure. SiO₂, Al₂O₃, or SiNₓ may be used to deposit the passivation layer 800 but is not limited thereto. The passivation layer 800 may be an insulating layer. For a clearer illustration, the following drawings allow the main layers to be visible even after the passivation layer 800 is deposited, but in reality, the main layers are not exposed to the outside.

Referring to FIG. 7, in the sixth step, the passivation layer 800 on the corner mesa contact structure is etched for electrical connection of each of the light-emitting structures.

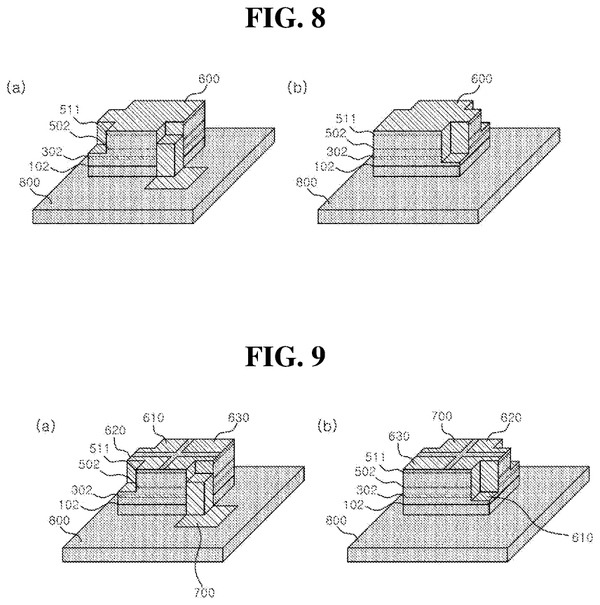

Referring to FIG. 8, in the seventh step, a metal contact 600 is deposited on the etched corner mesa contact structures to electrically connect each of the light-emitting structures.

Referring to FIG. 9, in the eighth step, the metal contact 600 located on the top of the corner mesa contact structure is divided into four parts by etching down to the passivation layer 800, thereby manufacturing a micro-light-emitting diode in which the contacts are individually operable.

The metal contact 600 consists of anodes 610, 620, and 630 and a common cathode 700. The anodes 610, 620, and 630 are collectively referred to as the first anode 610, the second anode 620, and the third anode 630 for convenience of notation, but the anodes individually operate. The first anode 610 is formed on the exposed portion of the first anode layer 301 to be electrically connected to the first active layer 102 and also be connected to an upper part of the corner mesa contact structure. The second anode 620 is formed on the exposed portion of the second anode layer 303 to be electrically connected to the second active layer 502 and also be connected to an upper part of the corner mesa contact structure. The third anode 630 is formed on the exposed portion of the passivation layer 800 at the top of the corner mesa contact structure to be electrically connected to the third active layer 511 and also be connected to an upper part of the corner mesa contact structure. The first active layer 102 emits light when a voltage is applied between the first anode 610 and the first n-type semiconductor layer 101. The second active layer 502 emits light when a voltage is applied between the second anode 620 and the second n-type semiconductor layer 503. The third active layer 511 emits light when a voltage is applied between the third anode 630 and the second n-type semiconductor layer 503. Meanwhile, the first n-type semiconductor layer 101 is electrically connected to the common cathode 700. This applies equally to the second anode 620 and the third anode 630. The common cathode 700 is formed on the exposed portions of the first n-type semiconductor layer 101 and the second n-type semiconductor layer 503 to be connected to an upper part of the corner mesa contact structure. In other words, the three light-emitting structures having the vertically-stacked structure are electrically connected to the common cathode 700, while the anodes are individually arranged.

### Second Embodiment

A different process is performed to manufacture a micro-light-emitting diode having corner mesa contact structures using the same vertically-stacked structure as the first embodiment.

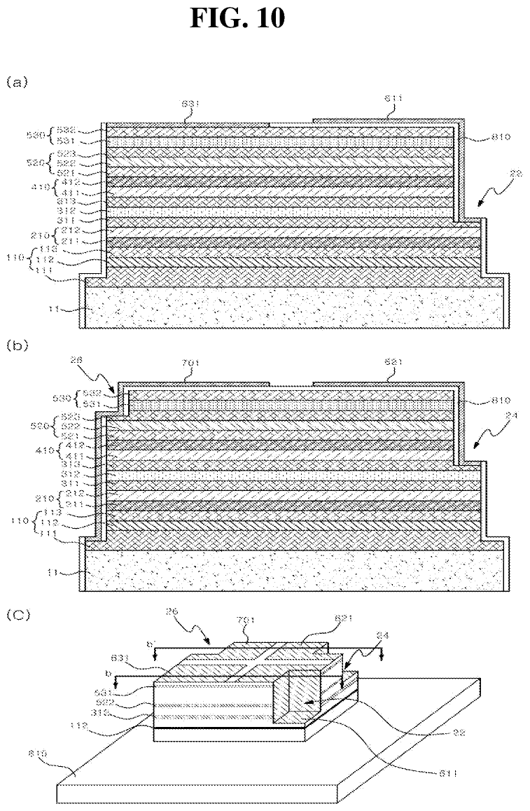

FIG. 10 show cross-sectional views and a perspective view of a micro-light-emitting diode according to an embodiment of the present inventive concept. In FIG. 10, (a) and (b) represent cross-sectional views obtained by cutting the perspective view of (c) in the directions of b and b′, respectively. Here, (a) is a cross-sectional view obtained by cutting the perspective view of (c) in the direction of a, and (b) is a cross-sectional view obtained by cutting the perspective view of (c) in the direction of a′. In FIG. 10, (a) and (b) may have omitted the passivation layer for convenience of understanding, and the perspective view of (c) provides a more accurate structure. The structure illustrated in FIG. 10 is the same as that of FIG. 1.

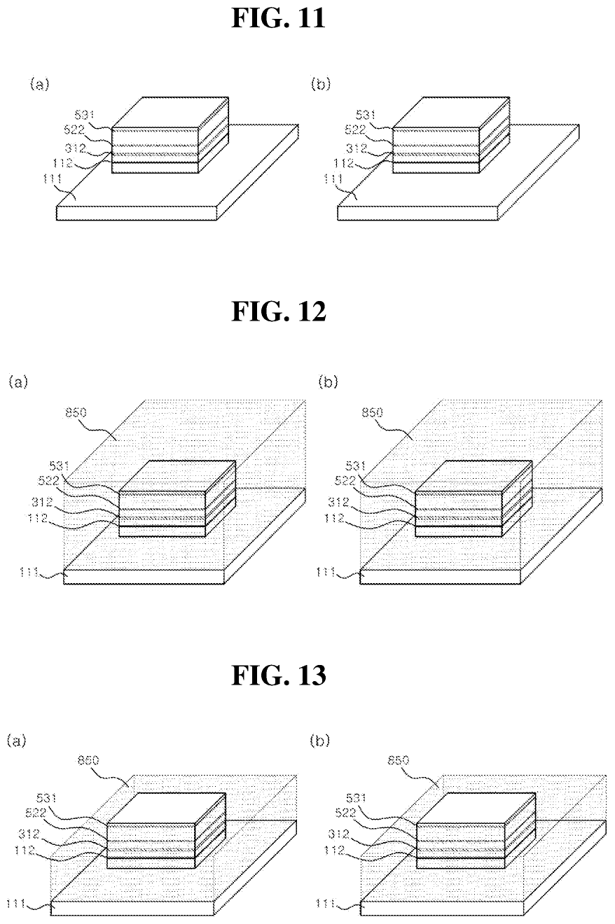

FIGS. 11 to 21 show perspective views illustrating the process of manufacturing a micro-light-emitting diode according to a second embodiment of the present inventive concept. The structure obtained by rotating (a) in FIGS. 11 to 21 by 180° is shown in (b), respectively.

Referring to FIGS. 11 to 21, the micro-light-emitting diode may be manufactured by a process including: a first step of forming a vertically-stacked structure including a pixel mesa structure by etching the vertically-stacked structure in a rectangular shape down to the first n-type semiconductor layer; a second step of depositing a protective layer on the vertically-stacked structure including the pixel mesa structure; a third step of removing a portion of the protective layer by performing chemical mechanical polishing (CMP) to planarize the top of the protective layer and the pixel mesa structure; a fourth step of forming a first contact hole at a first corner of the pixel mesa structure to form a first corner mesa contact structure; a fifth step of forming a second contact hole at a second corner of the pixel mesa structure to form a second corner mesa contact structure; a sixth step of forming a third contact hole at a third corner of the pixel mesa structure to form a third corner mesa contact structure; a seventh step of forming a vertically-stacked structure including the first to third corner mesa contact structures by removing the remaining protective layer on the vertically-stacked structure; an eighth step of forming a passivation layer on the vertically-stacked structure including the corner mesa contact structures formed in the seventh step; a ninth step of etching the passivation layer for electrode connections of the vertically-stacked structure; a tenth step of forming a metal contact to connect to the top of the etched vertically-stacked structure; and an eleventh step of dividing the metal contact formed in the tenth step into four parts by etching the metal contacts located on the top of the pixel mesa structure to be individually connected.

Referring to FIG. 11, the vertically-stacked structure shown in FIG. 10 is formed on a substrate. In the first step, a pixel mesa structure is formed by etching the vertically-stacked structure down to the top of the first n-type semiconductor layer 111 into a rectangular shape within the vertically-stacked structure.

Referring to FIG. 12, in the second step, a protective layer 850 including the pixel mesa structure is formed on the first n-type semiconductor layer 111. The protective layer 850 may be made of the same material used for the deposition of the passivation layer 800 in the first embodiment but is not limited thereto.

Referring to FIG. 13, in the third step, a portion of the protective layer 850 is removed by performing CMP down to the top of a third p-type semiconductor layer 532, which is the upper part of the pixel mesa structure, to planarize the top of the protective layer 850 and the pixel mesa structure.

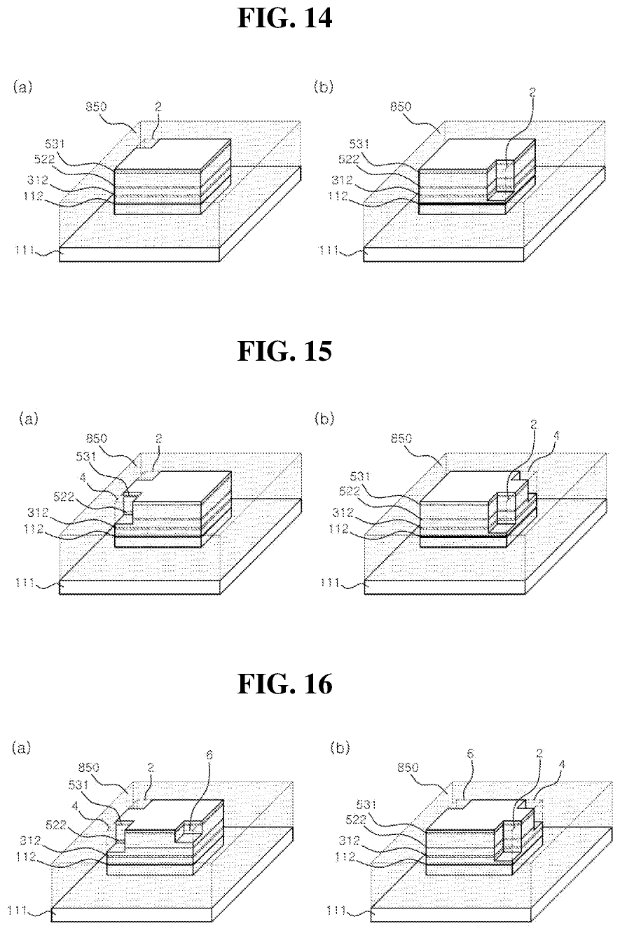

Referring to FIG. 14, in the fourth step, a first contact hole 2 is formed at a first corner of the pixel mesa structure to form a first corner mesa contact structure. One of the first anode layer 311, the second anode layer 313, and the second n-type semiconductor layer 523 is exposed through the first contact hole 2. The first contact hole 2 may be formed by removing the higher layers relative to the first anode layer 311 to expose a portion of the upper surface of the first anode layer 311.

In this embodiment, it is described that a portion of the upper surface of the first anode layer 311 is exposed through the first contact hole 2, but the layers exposed through the contact holes can be easily changed. That is, in the present inventive concept, the three contact holes expose the first anode layer 311, the second anode layer 313, and the second n-type semiconductor layer 523, respectively, but two or more contact holes do not share the exposed layers.

Referring to FIG. 15, in the fifth step, a second contact hole 4 is formed on the pixel mesa structure to form a second corner mesa contact structure in a first direction, which, in the perspective view of the figure, is vertical to the first contact hole 2. One of the first anode layer 311, the second anode layer 313, and the second n-type semiconductor layer 523 is exposed through the second contact hole 4. The second contact hole 4 may be formed by removing the higher layers relative to the second anode layer 313 to expose a portion of the upper surface of the second anode layer 313.

In this embodiment, it is described that a portion of the upper surface of the second anode layer 313 is exposed through the second contact hole 4, but the layers exposed through the contact holes can be easily changed.

Referring to FIG. 16, in the sixth step, a third contact hole 6 is formed on the pixel mesa structure to form a third corner mesa contact structure in a second direction, which, in the perspective view of the figure, is transverse to the second contact hole 4. One of the first anode layer 311, the second anode layer 313, and the second n-type semiconductor layer 523 is exposed through the third contact hole 6. The third contact hole 6 may be formed by removing the higher layers relative to the second n-type semiconductor layer 523 to expose a portion of the upper surface of the second n-type semiconductor layer 523.

In this embodiment, it is described that a portion of the upper surface of the second n-type semiconductor layer 523 is exposed through the third contact hole 6, but the layers exposed through the contact holes can be easily changed.

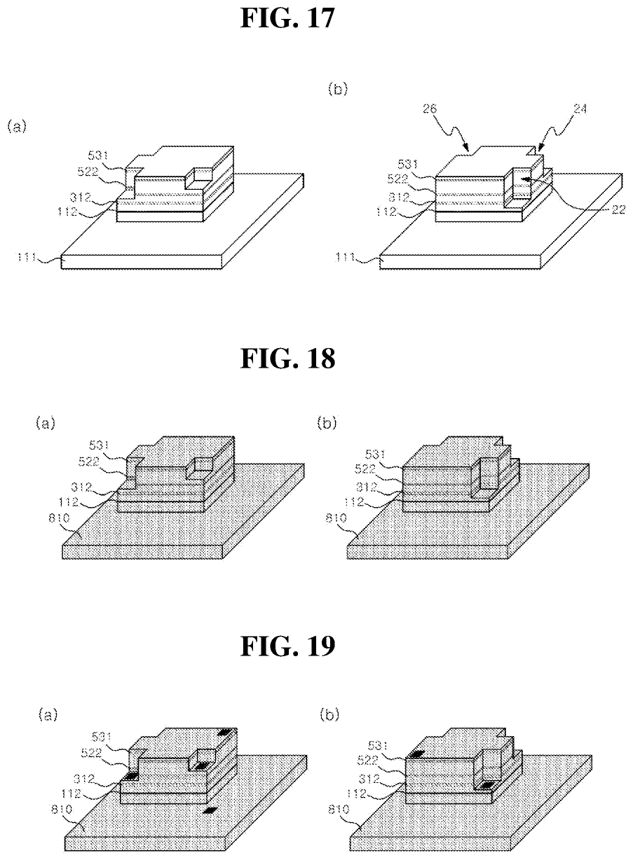

Referring to FIG. 17, in the seventh step, a vertically-stacked structure including the first to third corner mesa contact structures 22 to 26 is formed by removing the remaining protective layer 850 surrounding the pixel mesa structure in which the contact holes are formed. The first contact hole 2 corresponds to the first corner mesa contact structure 22, the second contact hole 4 corresponds to the second corner mesa contact structure 24, and the third contact hole 6 corresponds to the third corner mesa contact structure 26.

Referring to FIG. 18, in the eighth step, a passivation layer 810 is deposited on the vertically-stacked structure in which the corner mesa contact structures are formed. SiO₂, Al₂O₃, or SiNₓ may be used to deposit the passivation layer 810 but is not limited thereto. The passivation layer 810 may be an insulating layer.

Referring to FIG. 19, in the ninth step, the passivation layer 810 on the corner mesa contact structure is etched for electrical connection of each of the light-emitting structures.

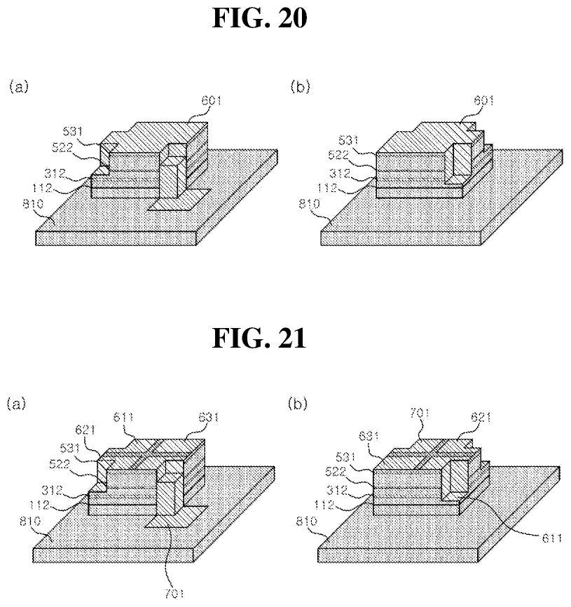

Referring to FIG. 20, in the tenth step, a metal contact 601 is deposited on the etched corner mesa contact structures to electrically connect each of the light-emitting structures.

Referring to FIG. 21, in the 11th step, the metal contact 601 located on the corner mesa contact structure is divided into four parts by etching down to the passivation layer 810, thereby manufacturing a micro-light-emitting diode in which the contacts are individually operable.

The metal contact consists of anodes 611, 621, and 631 and a common cathode 701. The anodes 611, 621, and 631 are collectively referred to as the first anode 611, the second anode 621, and the third anode 631 for convenience of notation, but the anodes individually operate.

The first anode 611 is formed on the exposed portion of the first anode layer 311 to be electrically connected to the first active layer 112 and also be connected to an upper part of the corner mesa contact structure. The second anode 621 is formed on the exposed portion of the second anode layer 313 to be electrically connected to the second active layer 522 and also be connected to an upper part of the corner mesa contact structure. The third anode 631 is formed on the exposed portion of the passivation layer 810 at the top of the corner mesa contact structure to be electrically connected to the third active layer 531 and also be connected to an upper part of the corner mesa contact structure. The first active layer 112 emits light when a voltage is applied between the first anode 611 and the first n-type semiconductor layer 111. The second active layer 522 emits light when a voltage is applied between the second anode 621 and the second n-type semiconductor layer 523. The third active layer 531 emits light when a voltage is applied between the third anode 631 and the second n-type semiconductor layer 523. Meanwhile, the first n-type semiconductor layer 111 is electrically connected to the common cathode 701. This applies equally to the second anode 621 and the third anode 631. The common cathode 701 is formed on the exposed portions of the first n-type semiconductor layer 111 and the second n-type semiconductor layer 523 to be connected to an upper part of the corner mesa contact structure. In other words, the three light-emitting structures having the vertically-stacked structure are electrically connected to the common cathode 701, while the anodes are individually arranged.

According to the present inventive concept as described above, the micro-light-emitting diode has a mesa structure that is approximately perpendicular at the corners, which minimizes the exposure of the active layers to the external environment, thereby reducing the occurrence of surface recombination, which is a primary cause of leakage current. As a result, it is possible to increase the lifespan of the micro-light-emitting diode. Moreover, due to the vertical etching direction, the manufacturing process is easier than before, and the unit area of the micro-light-emitting diode can be reduced with its stacked structure. Furthermore, the common electrode and other individual electrodes are formed on the same upper surface, which facilitates connection to external terminals in the subsequent wiring process, etc., and leads to a reduction in manufacturing costs. Particularly, the electrical contact process with external terminals can be performed very simply and effectively.

### Brief Description of Reference Numerals

1, 2: first contact hole
3, 4: second contact hole
5, 6: third contact hole
10: substrate
21, 22: first corner mesa contact structure
23, 24: second corner mesa contact structure
25, 26: third corner mesa contact structure
100, 110: first light-emitting structure
101, 111: first n-type semiconductor layer
102, 112: first active layer
103, 113: first p-type semiconductor layer
200, 201: first tunnel junction layer
201, 211, 402, 412: p⁺⁺-GaN layer
202, 212, 401, 411: n⁺⁺-GaN layer
301, 311: first anode layer
303, 313: second anode layer
302, 312: current blocking layer
400, 410: second tunnel junction layer
500, 520: second light-emitting structure
501, 511: second p-type semiconductor layer
502, 522: second active layer
503, 523: second n-type semiconductor layer
510, 530: third light-emitting structure
511, 531: third active layer
512, 532: third p-type semiconductor layer
600, 601: metal contact
610, 611: first anode
620, 621: second anode
630, 631: third anode
700, 701: common cathode
800, 810: passivation layer
850: protective layer

While the inventive concept has been shown and described with reference to certain preferred embodiments thereof, it will be understood by those skilled in the art that various changes in form and details may be made therein without departing from the spirit and scope of the inventive concept as defined by the appended claims. Therefore, the scope of the inventive concept is defined not by the detailed description of the inventive concept but by the appended claims, and all differences within the scope will be construed as being included in the present inventive concept.

What is claimed is:

1. A micro-light-emitting diode having corner mesa contact structures comprising:
a substrate;
a first light-emitting structure formed on the substrate;
a first tunnel junction layer formed on the light-emitting structure;
a first anode layer formed on the first tunnel junction layer;
a second anode layer formed on the first anode layer;
a second tunnel junction layer formed on the second anode layer;
a second light-emitting structure formed on the second tunnel junction layer; and
a third light-emitting structure formed on the second light-emitting structure,
wherein the micro-light-emitting diode has first to third corner mesa contact structures formed by removing the higher layers relative to the first anode layer, the second anode, and a second n-type semiconductor layer in the second light-emitting structure to expose a portion of the upper surface of the first anode layer, the second anode layer, and the second n-type semiconductor layer, and
wherein the micro-light-emitting diode comprises a cathode commonly connected to the first light-emitting structure and the second light-emitting structure and an anode formed on the surface of the third light-emitting structure, the first corner mesa contact structure, and the second corner mesa contact structure, respectively, the cathode and anode being connected to the top of the corner mesa contact structures, respectively.

2. The micro-light-emitting diode of claim 1, further comprising a current blocking layer formed between the first anode layer and the second anode layer.

3. The micro-light-emitting diode of claim 2, wherein the current blocking layer consists of a p-type semiconductor or an insulating material.

4. The micro-light-emitting diode of claim 1, wherein the first light-emitting structure comprises a first n-type semiconductor layer, a first active layer, and a first p-type semiconductor layer, which are sequentially stacked,
wherein the second light-emitting structure comprises a second p-type semiconductor layer, a second active layer, and a second n-type semiconductor layer, which are sequentially stacked, and
wherein the third light-emitting structure shares the second n-type semiconductor layer with the second light-emitting structure and comprises a third active layer and a third p-type semiconductor layer, which are sequentially stacked on the second n-type semiconductor layer.

5. The micro-light-emitting diode of claim 1, wherein the first anode layer and the second anode layer consist of an n-type semiconductor layer, the first anode layer being connected in a reverse bias to the current direction of the first light-emitting structure, and the second anode layer being connected in a reverse bias to the current direction of the second light-emitting structure.

6. The micro-light-emitting diode of claim 1, wherein the first light-emitting structure generates light of a first wavelength, the second light-emitting structure generates light of a second wavelength that is longer than the first wavelength, and the third light-emitting structure generates light of a third wavelength that is longer than the second wavelength.

7. The micro-light-emitting diode of claim 6, wherein the light of the first wavelength is blue (B), the light of the second wavelength is green (G), and the light of the third wavelength is red (R).

8. The micro-light-emitting diode of claim 1, wherein the first corner mesa contact structure is formed by removing the higher layers relative to the first anode layer to expose a portion of the upper surface of the first anode layer,
wherein the second corner mesa contact structure is formed by removing the higher layers relative to the second anode layer to expose a portion of the upper surface of the second anode layer, and
wherein the third corner mesa contact structure is formed by removing the higher layers relative to the second n-type semiconductor layer to expose a portion of the upper surface of the second n-type semiconductor layer.

9. A method of manufacturing a micro-light-emitting diode, comprising the steps of:
forming a first contact hole to form a first corner mesa contact structure on a vertically-stacked structure;
forming a second contact hole to form a second corner mesa contact structure in a first direction with respect to the first contact hole;
forming a third contact hole to form a third corner mesa contact structure in a second direction with respect to the second contact hole;
forming a vertically-stacked structure including the corner mesa contact structures by etching the vertically-stacked structure, which includes the first contact hole at a first corner, the second contact hole at a second corner, the third contact hole at a third corner, and no contact hole at a fourth corner, into a rectangular pixel mesa structure, down to the surface of the first n-type semiconductor layer.
depositing a passivation layer on the surface of the vertically-stacked structure including the corner mesa contact structures;
etching the passivation layer for electrical connection of the light-emitting structures on the vertically-stacked structure;
forming a metal contact to connect to the top of the vertically-stacked structure of the etched corner mesa contact structures; and
dividing the metal contact formed on the vertically-stacked structure into four parts and etching the metal contacts.

10. The method of manufacturing a micro-light-emitting diode of claim 9, wherein the corner mesa contact structures comprise first to third corner mesa contact structures,
wherein the first corner mesa contact structure is formed by removing the higher layers relative to the first anode layer to expose a portion of the upper surface of the first anode layer,
wherein the second corner mesa contact structure is formed by removing the higher layers relative to the second anode layer to expose a portion of the upper surface of the second anode layer, and
wherein the third corner mesa contact structure is formed by removing the higher layers relative to the second n-type semiconductor layer to expose a portion of the upper surface of the second n-type semiconductor layer.

11. The method of manufacturing a micro-light-emitting diode of claim 9, wherein the metal contact is used as a cathode and an anode,
wherein the cathode electrically connects the first n-type semiconductor layer and the second n-type semiconductor layer, and
wherein the anode is formed on the exposed portions of the third p-type semiconductor layer, the first anode layer, and second anode layer, respectively, the cathode and anode being connected to the top of the corner mesa contact structures, respectively.

12. A method of manufacturing a micro-light-emitting diode, comprising the steps of:
forming a vertically-stacked structure including a pixel mesa structure by etching the vertically-stacked structure down to the top of a first n-type semiconductor layer;
depositing a protective layer on the first n-type semiconductor layer of the vertically-stacked structure including the pixel mesa structure;
removing a portion of the protective layer by performing chemical mechanical polishing (CMP) down to the surface of a third p-type semiconductor layer to planarize the protective layer and the pixel mesa structure;
forming a first contact hole to form a first corner mesa contact structure at a first corner of the pixel mesa structure;
forming a second contact hole to form a second corner mesa contact structure at a second corner of the pixel mesa structure in a first direction with respect to the first contact hole;
forming a third contact hole to form a third corner mesa contact structure at a third corner of the pixel mesa structure in a second direction with respect to the second contact hole;
forming a vertically-stacked structure including the corner mesa contact structures by removing the remaining protective layer on the pixel mesa structure;
depositing a passivation layer on the surface of the vertically-stacked structure including the corner mesa contact structures;
etching the passivation layer for electrode connection of the corner mesa contact structures;
forming a metal contact to connect to the top of the vertically-stacked structure including the etched corner mesa contact structures; and
dividing the metal contact formed on the vertically-stacked structure into four parts and etching the metal contacts.

13. The method of manufacturing a micro-light-emitting diode of claim 12, wherein the corner mesa contact structures comprise first to third corner mesa contact structures,
wherein the first corner mesa contact structure is formed by removing the higher layers relative to the first anode layer to expose a portion of the upper surface of the first anode layer,
wherein the second corner mesa contact structure is formed by removing the higher layers relative to the second anode layer to expose a portion of the upper surface of the second anode layer, and
wherein the third corner mesa contact structure is formed by removing the higher layers relative to the second n-type semiconductor layer to expose a portion of the upper surface of the second n-type semiconductor layer.

14. The method of manufacturing a micro-light-emitting diode of claim 12, wherein the metal contact is used as a cathode and an anode,
wherein the cathode electrically connects the first n-type semiconductor layer and the second n-type semiconductor layer, and
wherein the anode is formed on the exposed portions of the third p-type semiconductor layer, the first anode layer, and second anode layer, respectively, the cathode and anode being connected to the top of the corner mesa contact structures, respectively.
